(19) United States
(12) Patent Application Publication
(10) Pub. No.: US 2023/0307535 A1
(43) Pub. Date: Sep. 28, 2023

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Katsuhisa TANAKA, Himeji Hyogo (JP); Hiroshi KONO, Himeji Hyogo (JP)

(21) Appl. No.: 17/901,732

(22) Filed: Sep. 1, 2022

(30) Foreign Application Priority Data
Mar. 23, 2022 (JP) 2022-046944

(51) Int. Cl. H01L 29/78; H01L 29/06; H01L 29/10

(52) U.S. Cl. CPC H01L 29/7811; H01L 29/0623; H01L 29/063; H01L 29/1095; H01L 29/7813

(57) ABSTRACT

A semiconductor device includes a first electrode, a first semiconductor region of a first conductivity type having first and second regions, a second semiconductor region of a second conductivity type, a third semiconductor region of the first conductivity type, a gate electrode, a fourth semiconductor region of the second conductivity type between the first region and the gate electrode, fifth semiconductor regions of the second conductivity type, each having a first concentration of impurities of the second conductivity type, sixth semiconductor regions of the second conductivity type, each having a second concentration of impurities of the second conductivity type that is lower than the first concentration, and a second electrode. The fifth semiconductor regions are located around the fourth semiconductor region in a first plane perpendicular to the first direction. The sixth semiconductor regions are located around the second semiconductor region in a second plane perpendicular to the first direction.

### CROSS-REFERENCE TO RELATED APPLICATION(S)

This application is based upon and claims the benefit of priority from Japanese Patent Application No. 2022-046944, filed Mar. 23, 2022, the entire contents of which are incorporated herein by reference.

### FIELD

Embodiments described herein relate generally to a semiconductor device.

### BACKGROUND

Semiconductor devices such as a metal oxide semiconductor field-effect transistor (MOSFET) are used in applications such as power conversion. It is desirable that such semiconductor devices have a high breakdown voltage.

### DESCRIPTION OF THE DRAWINGS

FIG. 1 is a plan view showing a semiconductor device according to a first embodiment.

FIG. 2 is a sectional view taken along line A1-A2 of FIGS. 1 and 3.

FIG. 3 is another plan view showing the semiconductor device according to the first embodiment.

FIG. 4 is a sectional view taken along line B1-B2 of FIGS. 1 and 3.

FIG. 5 is a sectional view showing a part of a semiconductor device according to a first modification of the first embodiment.

FIGS. 6A and 6B are plan views, each showing a part of the semiconductor device according to the first modification of the first embodiment.

FIG. 7 is a sectional view showing a part of a semiconductor device according to a second embodiment.

FIG. 8 is a sectional view showing a part of a semiconductor device according to a first modification of the second embodiment.

FIG. 9 is a sectional view showing a part of a semiconductor device according to a third embodiment.

FIG. 10 is a sectional view showing a part of a semiconductor device according to a first modification of the third embodiment.

FIG. 11 is a sectional view showing a part of a semiconductor device according to a second modification of the third embodiment.

FIG. 12 is a sectional view showing a part of a semiconductor device according to a third modification of the third embodiment.

FIG. 13 is a sectional view showing a part of a semiconductor device according to a fourth modification of the third embodiment.

### DETAILED DESCRIPTION

Embodiments provide a semiconductor device whose breakdown voltage can be increased.

In general, according to one embodiment, a semiconductor device includes a first electrode, a first semiconductor region of a first conductivity type, a second semiconductor region of a second conductivity type, a third semiconductor region of the first conductivity type, a gate electrode, a fourth semiconductor region of the second conductivity type, a plurality of fifth semiconductor regions of the second conductivity type, a plurality of sixth semiconductor regions of the second conductivity type, and a second electrode. The first semiconductor region is provided on the first electrode in a first direction and includes a first region and a second region provided around the first region. The second semiconductor region is provided on the first region. The third semiconductor region is provided on a part of the second semiconductor region. The gate electrode faces the second semiconductor region with a gate insulation layer placed therebetween. The fourth semiconductor region is provided between the first region and the gate electrode. The plurality of fifth semiconductor regions are each provided in the second region and located around the fourth semiconductor region in a first plane perpendicular to the first direction. They are separated from each other in a second direction that extends from the first region to the second region. The plurality of sixth semiconductor regions are provided in the second region, located around the second semiconductor region in a second plane perpendicular to the first direction, and separated from each other in the second direction. Each of the plurality of sixth semiconductor regions has a concentration of impurities of the second conductivity type which is lower than a concentration of impurities of the second conductivity type of each of the plurality of fifth semiconductor regions. The second electrode is provided on the second semiconductor region and the third semiconductor region.

Hereinafter, embodiments of the present disclosure will be described with reference to the drawings.

The drawings are schematic or conceptual drawings and the relationship between the thickness and width of each portion and the ratio between the sizes of the portions, for example, may not be representative of the actual relationships and ratios. A portion is sometimes illustrated so as to have different sizes or ratios in different drawings.

In the following description and drawings, characters n⁺, n, n⁻, p⁺, p, and p⁻ each indicate the relative level of each concentration of impurities. That is, a character with indicates that a concentration of impurities is relatively higher than that of a character without “+” and “−” and a character with “−” indicates that a concentration of impurities is relatively lower than that of a character without “+” and “−”. When both p-type impurities and n-type impurities are contained in each region, these characters indicate the relative level of a net concentration of impurities observed after these impurities cancel each other.

Each of the embodiments, which will be described below, may be carried out with a p-type semiconductor region changed to an n-type semiconductor region and vice versa.

First Embodiment

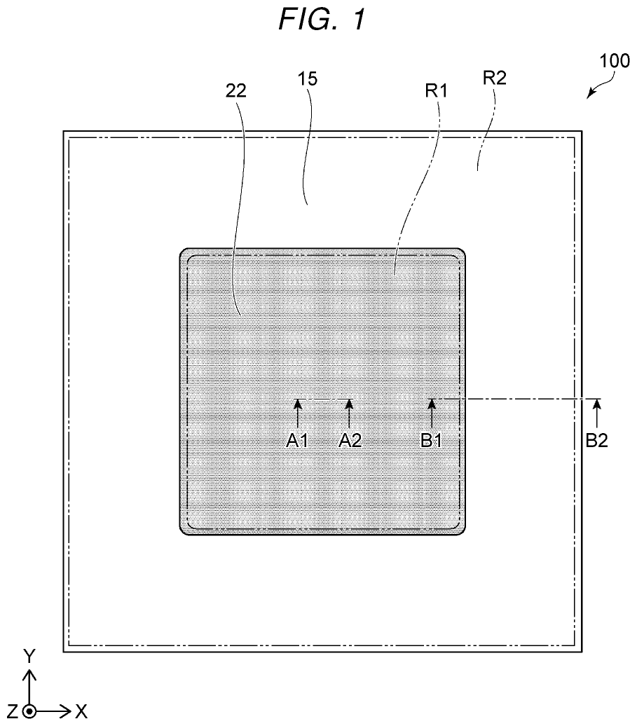

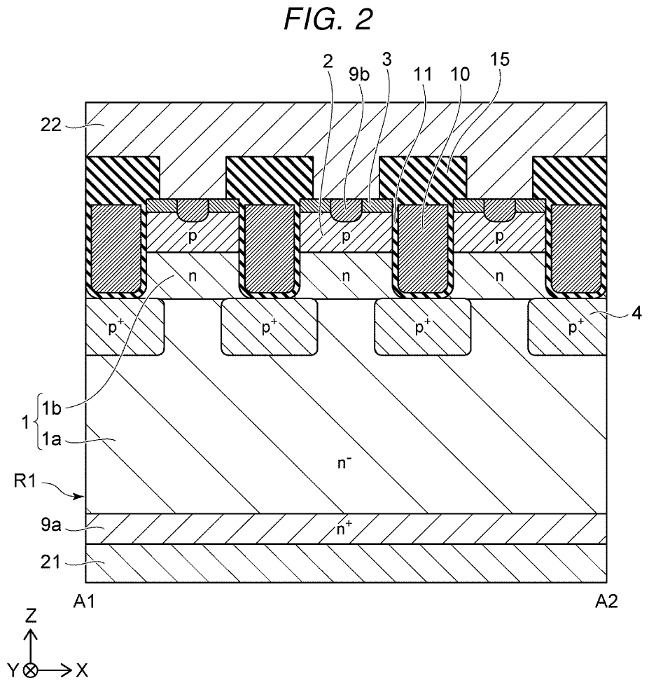

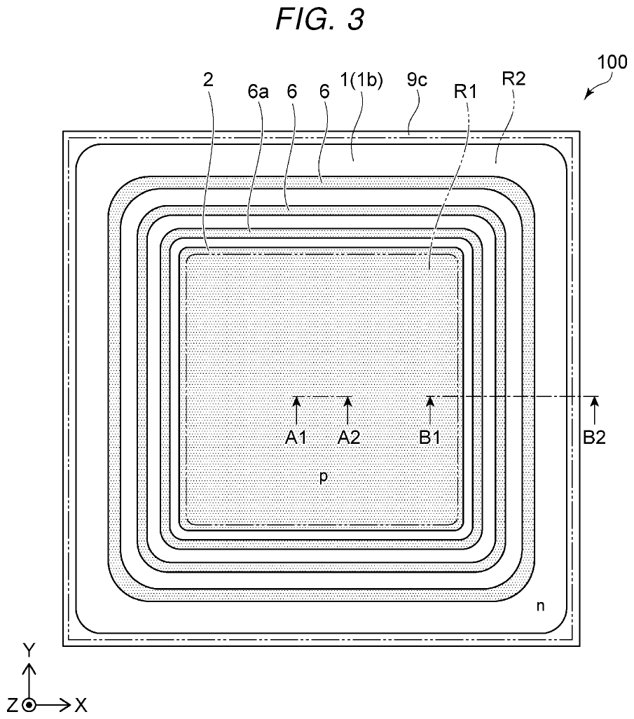

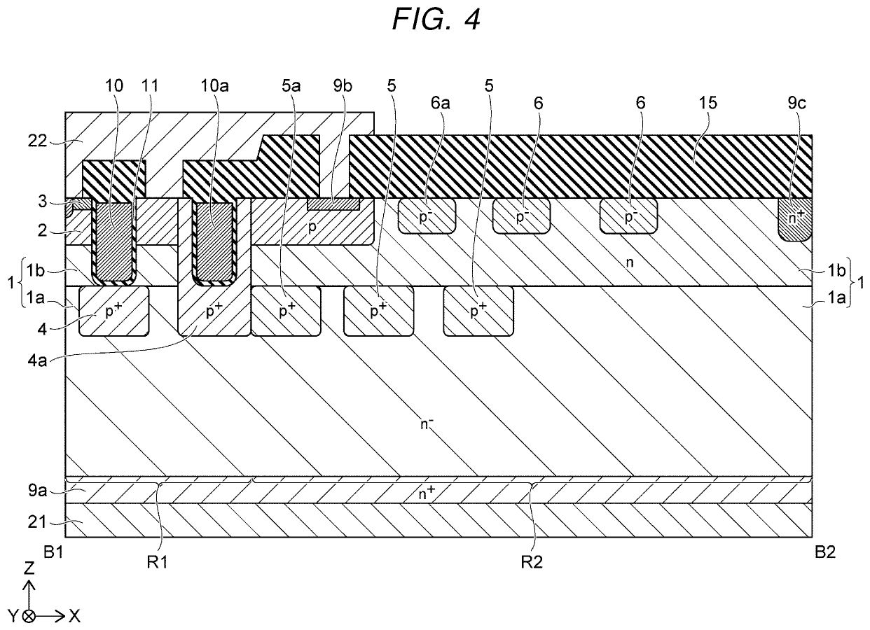

FIGS. 1 and 3 are plan views showing a semiconductor device according to a first embodiment. FIG. 2 is a sectional view taken along line A1-A2 of FIGS. 1 and 3. FIG. 4 is a sectional view taken along line B1-B2 of FIGS. 1 and 3. An n⁺-type source region 3, a p⁺-type contact region 9b, a gate electrode 10, an insulating layer 15, a source electrode 22 and so forth are not shown in FIG. 3.

The semiconductor device according to the first embodiment is a MOSFET. As shown in FIGS. 1 to 4, a semiconductor device 100 according to the first embodiment includes an n⁻-type (referred to herein as a first conductivity type) drift region 1 (referred to herein as a first semiconductor region), a p-type (referred to herein as a second conductivity type) base region 2 (referred to herein as a second semiconductor region), an n⁺-type source region 3 (referred to herein as a third semiconductor region), a p⁺type semiconductor region 4 (referred to herein as a fourth semiconductor region), a p⁺-type semiconductor region 5 (which is one example of a fifth semiconductor region), a p⁻-type semiconductor region 6 (which is one example of a sixth semiconductor region), an n⁺-type drain region 9a, a p⁺-type contact region 9b, an n⁺-type semiconductor region 9c, a gate electrode 10, a drain electrode 21 (referred to herein as a first electrode), and a source electrode 22 (referred to herein as a second electrode).

An XYZ orthogonal coordinate system is used in describing the embodiments. A direction from the drain electrode 21 to the n⁻-type drift region 1 is assumed to be the Z direction (referred to herein as a first direction). One direction orthogonal to the Z direction is assumed to be the X direction. A direction orthogonal to the X direction and the Z direction is assumed to be the Y direction. Moreover, in the following description, a direction from the drain electrode 21 to the n⁻-type drift region 1 is referred to as “up” and a direction opposite to this direction is referred to as “down”. These directions are directions based on the relative positional relationship between the drain electrode 21 and the n⁻-type drift region 1 and have no relation to the direction of gravity.

As shown in FIG. 1, the source electrode 22 is provided on the upper surface of the semiconductor device 100. The periphery of the source electrode 22 is covered with an insulating layer 15.

As shown in FIGS. 2 and 4, the drain electrode 21 is provided on the lower surface of the semiconductor device 100. The n⁺-type drain region 9a is provided on the drain electrode 21 and electrically connected to the drain electrode 21. The n⁻-type drift region 1 is provided on the n⁺-type drain region 9a. The n⁻-type drift region 1 is electrically connected to the drain electrode 21 via the n⁺-type drain region 9a.

As shown in FIGS. 1 to 4, the n⁻-type drift region 1 includes a first region R1 and a second region R2. The second region R2 is provided around the first region R1 along an X-Y plane (referred to herein as a first plane). The first region R1 corresponds to an element region of the semiconductor device 100. The second region R2 corresponds to a termination region of the semiconductor device 100.

As shown in FIG. 2, the p-type base region 2 is provided on the first region R1. The n⁺-type source region 3 and the p⁺-type contact region 9b are selectively provided on the p-type base region 2.

The gate electrode 10 faces the p-type base region 2 with a gate insulation layer 11 placed therebetween in the X direction. Additionally, in an example shown in FIG. 2, the gate electrode 10 faces a part of the n⁻-type drift region 1 and a part of the n⁺-type source region 3 with the gate insulation layer 11 placed therebetween. The p⁺-type semiconductor region 4 is provided between the n⁻-type drift region 1 and the gate electrode 10 in the Z direction. The concentration of p-type impurities of the p⁺-type semiconductor region 4 is higher than the concentration of p-type impurities of the p-type base region 2. The p⁺-type semiconductor region 4 is separated from the p-type base region 2.

As shown in FIG. 2, the n⁻-type drift region 1 may include portions 1a and 1b having different concentrations of n-type impurities. The portion 1b is provided between the portion 1a and the p-type base region 2 in the Z direction and lies side-by-side with the gate electrode 10 in the X direction. The concentration of n-type impurities of the portion 1b is higher than the concentration of n-type impurities of the portion 1a.

A plurality of portions 1b, a plurality of n⁺-type source regions 3, a plurality of p⁺-type semiconductor regions 4, a plurality of p⁺-type contact regions 9b, and a plurality of gate electrodes 10 are provided in the X direction and each of them extends in the Y direction. As shown in FIGS. 2 to 4, the p-type base region 2 is provided between the gate electrodes 10 and around the plurality of gate electrodes 10.

As shown in FIGS. 1 and 2, the source electrode 22 is provided on the first region R1 and located on the plurality of n⁺-type source regions 3 and the plurality of p⁺-type contact regions 9b. The source electrode 22 is electrically connected to the plurality of n⁺-type source regions 3 and the plurality of p⁺-type contact regions 9b. The p-type base region 2 is electrically connected to the source electrode 22 via the p⁺-type contact region 9b. The gate electrode 10 is electrically separated from the source electrode 22 by the insulating layer 15.

As shown in FIG. 4, the p⁺-type semiconductor region 5 is provided in the second region R2. As shown in FIGS. 3 and 4, the p⁻-type semiconductor region 6 and the n⁺-type semiconductor region 9c are provided in the second region R2. The p⁻-type semiconductor region 6 is located around the p-type base region 2 in the X-Y plane. The concentration of p-type impurities of the p⁻-type semiconductor region 6 is lower than the concentration of p-type impurities of the p-type base region 2. A plurality of p⁻-type semiconductor regions 6 are provided in a direction (a radial direction: referred to herein as a second direction) from the first region R1 to the second region R2. The radial direction is parallel to the X-Y plane. The p⁻-type semiconductor regions 6 are separated from each other and the space between the adjacent p⁻-type semiconductor regions 6 increases at positions farther from the center in the radial direction.

The p⁺-type semiconductor region 5 is located around the plurality of p⁺-type semiconductor regions 4 in the X-Y plane. The concentration of p-type impurities of the p⁺-type semiconductor region 5 may be the same as the concentration of p-type impurities of the p⁺-type semiconductor region 4 or may be different therefrom. The concentration of p-type impurities of the p⁺-type semiconductor region 5 is higher than the concentration of p-type impurities of the p-type base region 2 and higher than the concentration of p-type impurities of the p⁻-type semiconductor region 6. As in the case of the p⁻-type semiconductor region 6, a plurality of p⁺-type semiconductor regions 5 are provided in the radial direction. The p⁺-type semiconductor regions 5 are separated from each other and the space between the adjacent p⁺-type semiconductor regions 5 increases at positions farther from the center in the radial direction. Moreover, the plurality of p⁻-type semiconductor regions 6 are separated from the plurality of p⁺-type semiconductor regions 5 in the Z direction.

The n⁺-type semiconductor region 9c is located around the plurality of p⁻-type semiconductor regions 6 in the X-Y plane. The n⁺-type semiconductor region 9c is separated from the plurality of p⁻-type semiconductor regions 6 and provided along the outer periphery of the semiconductor device 100. The concentration of n-type impurities of the n⁺-type semiconductor region 9c is higher than the concentration of n-type impurities of the portion 1b. The insulating layer 15 is provided on a part of the portion 1b and on the plurality of p⁻-type semiconductor regions 6 and the n⁺-type semiconductor region 9c. That is, in the second region R2, a part of the portion 1b, the plurality of p⁻-type semiconductor regions 6, and the n⁺-type semiconductor region 9c are covered with the insulating layer 15.

As shown in FIG. 4, of the plurality of p⁺-type semiconductor regions 4, the p⁺-type semiconductor region 4 that is located at an end thereof in the X direction is depicted as a p⁺-type semiconductor region 4a. The p⁺-type semiconductor region 4a abuts the p-type base region 2. In this case, an electrode 10a surrounded with the p⁺-type semiconductor region 4a may function as a gate electrode. The electrode 10a, however, does not have to function as a gate electrode and instead may be a floating electrode, for example. The electrode 10a may be electrically connected to the gate electrode 10 or may be electrically separated from the gate electrode 10. Of the plurality of p⁺-type semiconductor regions 5, the p⁺-type semiconductor region 5 that is closest to the first region R1 is depicted as a p⁺-type semiconductor region 5a. The p⁺-type semiconductor region 5a abuts the p⁺-type semiconductor region 4a. In this case, the p⁺-type semiconductor region 5a is electrically connected to the source electrode 22 via the p⁺-type semiconductor region 4a and the p-type base region 2. Of the plurality of p⁻-type semiconductor regions 6, the p⁻-type semiconductor region 6 that is closest to the first region R1 is depicted as the p⁻-type semiconductor region 6a. The p⁻-type semiconductor region 6a is separated from the p-type base region 2 as shown or, alternatively, it may abut the p-type base region 2.

An operation of the semiconductor device 100 will be described.

A voltage that is greater than or equal to a threshold value is applied to the gate electrode 10 in a state in which a voltage that is positive with respect to the source electrode 22 is applied to the drain electrode 21. This causes a channel (an inversion layer) to be formed in the p-type base region 2 and the semiconductor device 100 enters an ON state. Electrons flow into the n⁻-type drift region 1 from the source electrode 22 through the channel and move toward the drain electrode 21. This allows a current to flow through the first region R1. When the voltage that is applied to the gate electrode 10 becomes smaller than the threshold value, the channel in the p-type base region 2 disappears and the semiconductor device 100 enters an OFF state.

One example of a material for each component of the semiconductor device 100 will be described.

The n⁻-type drift region 1, the p-type base region 2, the n⁺-type source region 3, the p⁺-type semiconductor region 4, the p⁺-type semiconductor region 5, the p⁻-type semiconductor region 6, the n⁺-type drain region 9a, the p⁺-type contact region 9b, and the n⁺-type semiconductor region 9c contain a semiconductor material. Silicon carbide, silicon, gallium nitride, or gallium arsenide may be used as the semiconductor material. Arsenic, phosphorus, or antimony may be used as n-type impurities. Boron may be used as p-type impurities.

The gate electrode 10 contains a conductive material such as polysilicon. To the gate electrode 10, n-type or p-type impurities may be added. The gate insulation layer 11 and the insulating layer 15 contain an electrical insulating material. For example, the gate insulation layer 11 and the insulating layer 15 contain silicon oxide, silicon nitride, or silicon oxynitride. The drain electrode 21 and the source electrode 22 contain metal such as titanium, tungsten, or aluminum.

Advantages of the first embodiment will be described. In the semiconductor device 100, the p⁺-type semiconductor region 4 is provided between the n⁻-type drift region 1 and the gate electrode 10. By providing the p⁺-type semiconductor region 4, it is possible to reduce electric field concentration near a lower end of the gate insulation layer 11 when the semiconductor device 100 is OFF and prevent a breakdown of the gate insulation layer 11. On the other hand, when the p⁺-type semiconductor region 4 is provided, electric field concentration occurs between the n⁻-type drift region 1 and the p⁺-type semiconductor region 4. To increase the breakdown voltage of the semiconductor device 100, it is also preferable to reduce the electric field concentration near the p⁺-type semiconductor region 4.

In particular, in the semiconductor device 100 in which each semiconductor region contains silicon carbide, the critical electric field is higher than the critical electric field of an insulating material such as silicon oxide. Thus, if the p⁺-type semiconductor region 4 is not provided, when a high voltage is applied to the semiconductor device 100 in an OFF state, an excessive voltage is applied to the gate insulation layer 11, which could cause an electrical breakdown of the gate insulation layer 11. For this reason, in the semiconductor device 100 using silicon carbide, it is more desirable to provide the p⁺-type semiconductor region 4 as compared to the semiconductor device 100 using silicon.

In the semiconductor device 100 according to the first embodiment, the plurality of p⁺-type semiconductor regions 5 are provided around the p⁺-type semiconductor region 4. By providing the p⁺-type semiconductor region 5 in the second region R2 which is a termination region, it is possible to expand the electric field distribution toward the outer periphery of the semiconductor device 100 and reduce electric field concentration near the p⁺-type semiconductor region 4. Moreover, by providing the plurality of p⁻-type semiconductor regions 6 also on the second region R2 around the p-type base region 2, it is also possible to reduce electric field concentration on the outer periphery of the p-type base region 2.

In particular, in the semiconductor device 100, the concentration of p-type impurities of the p⁺-type semiconductor region 5 is higher than the concentration of p-type impurities of the p⁻-type semiconductor region 6. By increasing the concentration of p-type impurities of the p⁺-type semiconductor region 5, it is possible to further expand the electric field distribution toward the outer periphery of the semiconductor device 100 in a location where the p⁺-type semiconductor region 4 is provided. This makes it possible to further reduce electric field concentration and further increase the breakdown voltage of the semiconductor device 100.

Furthermore, the p⁺-type semiconductor region 5 is located inside a semiconductor layer, not on the front surface of the semiconductor layer, and is not completely depleted when the semiconductor device 100 is OFF. Therefore, electric field concentration occurs near the p⁺-type semiconductor region 5 when the semiconductor device 100 is OFF. In other words, electric field concentration occurs in a location away from the interface between the semiconductor region (the p⁻-type semiconductor region 6 and the portion 1b) and the insulating layer 15.

A carrier trap level exists at the interface between the semiconductor region and the insulating layer 15. When electric field concentration occurs near this interface, a carrier accelerated by the electric field is trapped, which could affect the electric field distribution in the second region R2. By providing the p⁺-type semiconductor region 5, it is possible to reduce electric field concentration near the interface between the semiconductor region and the insulating layer 15. With the plurality of p⁻-type semiconductor regions 6, it is possible to stabilize the electric field distribution expanded toward the outer periphery of the semiconductor device 100 and reduce fluctuations of the breakdown voltage of the semiconductor device 100.

First Modification

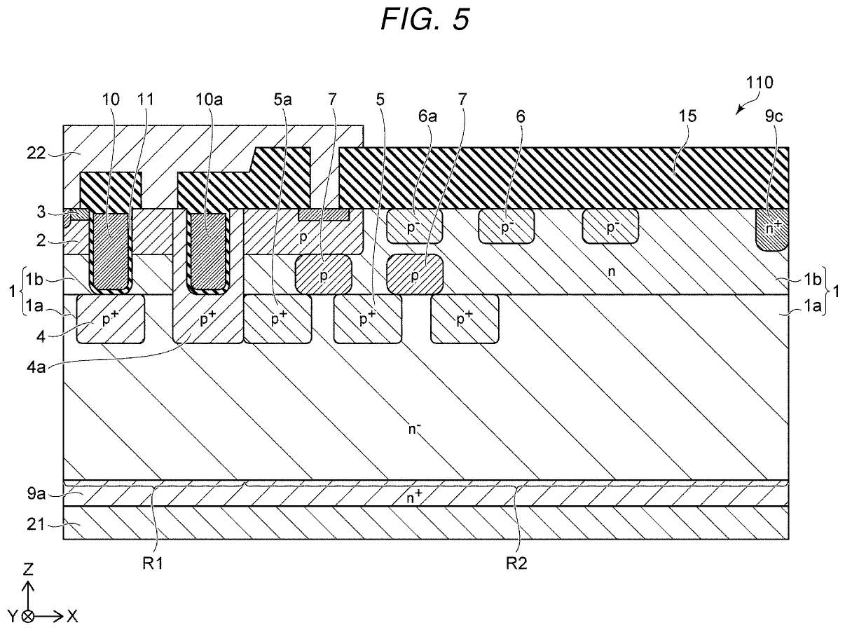

FIG. 5 is a sectional view showing a part of a semiconductor device according to a first modification of the first embodiment.

A semiconductor device 110 according to the first modification is different from the semiconductor device 100 in that the semiconductor device 110 further includes a p-type semiconductor region 7 (which is an example of a seventh semiconductor region). As shown in FIG. 5, the p-type semiconductor region 7 is provided in the second region R2 and located around the gate electrode 10 in the X-Y plane. The p-type semiconductor region 7 is located above the p⁺-type semiconductor region 5 and located below the p⁻-type semiconductor region 6. As in the case of the p⁺-type semiconductor region 5 and the p⁻-type semiconductor region 6, a plurality of p-type semiconductor regions 7 are provided in the X direction and the Y direction. The p-type semiconductor regions 7 are separated from each other.

The concentration of p-type impurities of the p-type semiconductor region 7 is lower than the concentration of p-type impurities of the p⁺-type semiconductor region 5 and higher than the concentration of p-type impurities of the p⁻-type semiconductor region 6. The concentration of p-type impurities of the p-type semiconductor region 7 may be the same as the concentration of p-type impurities of the p-type base region 2 or may be different therefrom. Moreover, at least any one of the plurality of p-type semiconductor regions 7 may abut the p-type base region 2 as depicted. In addition, any one of the plurality of p-type semiconductor regions 7 may abut any one of the plurality of p⁺-type semiconductor regions 5 as depicted or any one of the plurality of p⁻-type semiconductor regions 6 (not depicted).

According to the first modification, providing the plurality of p-type semiconductor regions 7 makes a depletion layer more likely to spread in the Z direction on the outer periphery of the p-type base region 2. As compared with the semiconductor device 100, it is possible to further reduce the electric field strength in the Z direction on the outer periphery of the p-type base region 2 and further increase the breakdown voltage of the semiconductor device 110.

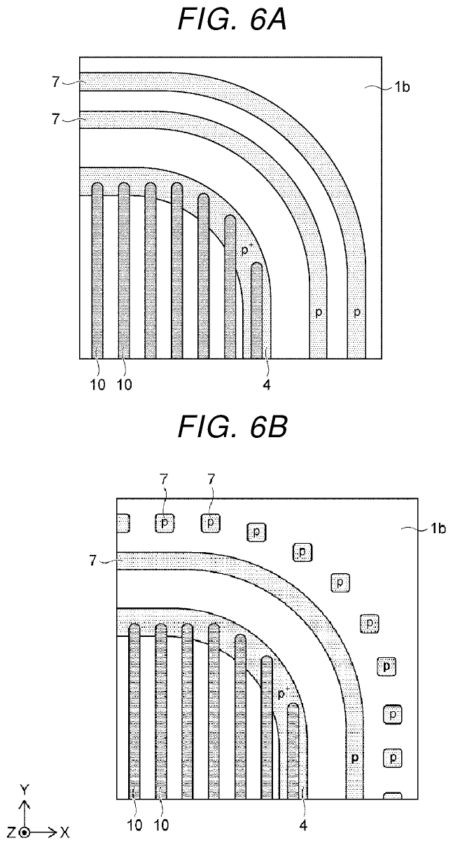

FIGS. 6A and 6B are plan views, each showing a part of the semiconductor device 110 according to the first modification of the first embodiment.

FIGS. 6A and 6B each show a planar structure in a location where the p-type semiconductor region 7 is provided. As shown in FIG. 6A, each of the plurality of p-type semiconductor regions 7 may be continuously provided around the plurality of gate electrodes 10. As shown in FIG. 6B, the plurality of p-type semiconductor regions 7 may be arranged in a circumferential direction around the plurality of gate electrodes 10. Likewise, each of the plurality of p⁺-type semiconductor regions 5 may be continuously provided around the plurality of gate electrodes 10. The plurality of p⁺-type semiconductor regions 5 may be arranged in the circumferential direction around the plurality of gate electrodes 10.

As compared with the structure shown in FIG. 6B, the structure shown in FIG. 6A makes it possible to increase the stability of electric field distribution in the second region R2 and stabilize the breakdown voltage of the semiconductor device 110. In the structure shown in FIG. 6B, the length of the second region R2 in the radial direction can be made shorter than the length of the second region R2 in the structure shown in FIG. 6A by changing the density of the p-type semiconductor regions 7 in accordance with the electric field strength in the second region R2. For example, the electric field strength tends to be high near a corner portion of the p-type base region 2 when viewed from the Z direction shown in FIG. 6B as compared to the other regions. By making the density of the p-type semiconductor regions 7 near the corner portion higher than the density of the p-type semiconductor regions 7 in the other regions, it is possible to increase the breakdown voltage of the semiconductor device 110 while suppressing an increase in the length of the second region R2.

Second Embodiment

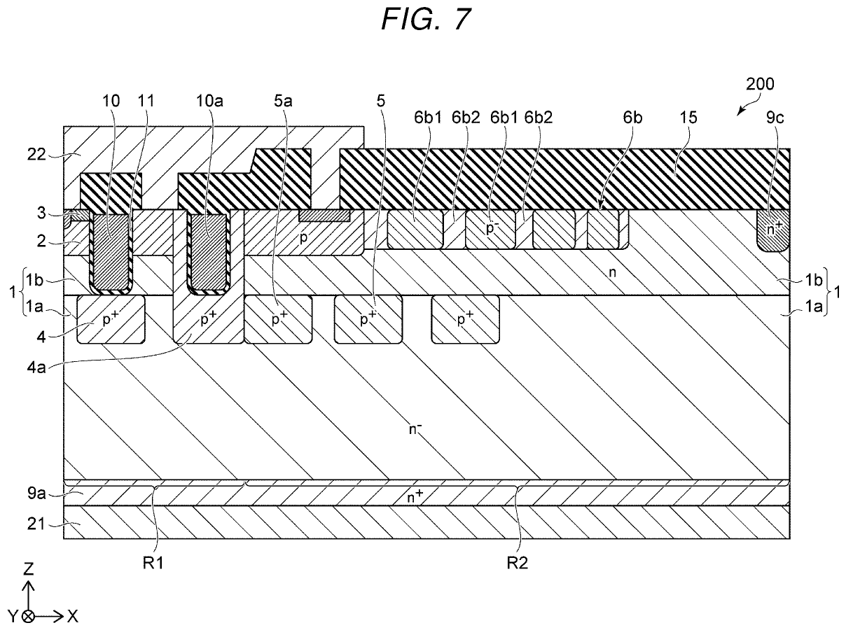

FIG. 7 is a sectional view showing a part of a semiconductor device according to a second embodiment.

When compared with the semiconductor device 100, a semiconductor device 200 according to the second embodiment shown in FIG. 7 includes a p⁻-type semiconductor region 6b (which is another example of the sixth semiconductor region) in place of the p⁻-type semiconductor region 6. The p⁻-type semiconductor region 6b is provided around the p-type base region 2 in the X-Y plane and abuts the p-type base region 2. The p⁻-type semiconductor region 6b includes first portions 6b1 and second portions 6b2. The concentration of p-type impurities of the first portion 6b1 is higher than the concentration of p-type impurities of the second portion 6b2. The first portions 6b1 and the second portions 6b2 are alternately provided in the radial direction.

The concentration of p-type impurities of the first portion 6b1 and the concentration of p-type impurities of the second portion 6b2 are lower than the concentration of p-type impurities of the p-type base region 2 and lower than the concentration of p-type impurities of the p⁺-type semiconductor region 5. Moreover, in the example shown in FIG. 7, the width of the first portion 6b1 decreases at positions farther from the center in the radial direction to make the concentration of p-type impurities per unit area of the p⁻-type semiconductor region 6b including the first portions 6b1 and the second portions 6b2 decrease toward the outer periphery of the semiconductor device 200. The “width” as used herein corresponds to the length in the radial direction.

The width of the second portion 6b2 may also decrease toward the outer periphery of the semiconductor device 200 so long as the concentration of p-type impurities per unit area of the p⁻-type semiconductor region 6b decreases toward the outer periphery of the semiconductor device 200.

Suppressing a local increase in the electric field strength in the second region R2 is effective to increase the breakdown voltage of the semiconductor device 200. The lower the gradient of the concentration of p-type impurities in the radial direction is in a region around the p-type base region 2, the more effectively local electric field concentration can be reduced and the electric field strength in a spot where electric field concentration occurred can be reduced. In the semiconductor device 200, the width of the first portion 6b1 with a relatively high concentration of p-type impurities decreases in the radial direction. A decrease in the width of the first portion 6b1 makes the concentration of p-type impurities per unit area of the p⁻-type semiconductor region 6b decrease in the radial direction. By increasing the number of first portions 6b1 and reducing the difference in width between the adjacent first portions 6b1, it is possible to make lower the gradient of the concentration of p-type impurities per unit area. According to the second embodiment, it is possible to suppress an increase in the electric field strength in the second region R2 and increase the breakdown voltage of the semiconductor device 200.

There is a method of making the first portions 6b1 have different concentrations of p-type impurities to vary a concentration of p-type impurities per unit area. This method, however, makes it necessary to perform as many ion implantation processes as the number of first portions 6b1 having different concentrations of p-type impurities. In contrast to this, a plurality of first portions 6b1 having different widths can be formed by one ion implantation operation using a mask. The widths of the first portions 6b1 can be controlled by adjusting the widths of openings of the mask. Likewise, a plurality of second portions 6b2 can be formed by one ion implantation operation using a mask. By adjusting a concentration of p-type impurities per unit area by varying the width of the first portion 6b1, it is possible to more easily form the p⁻-type semiconductor region 6b having a low-gradient concentration of impurities.

First Modification

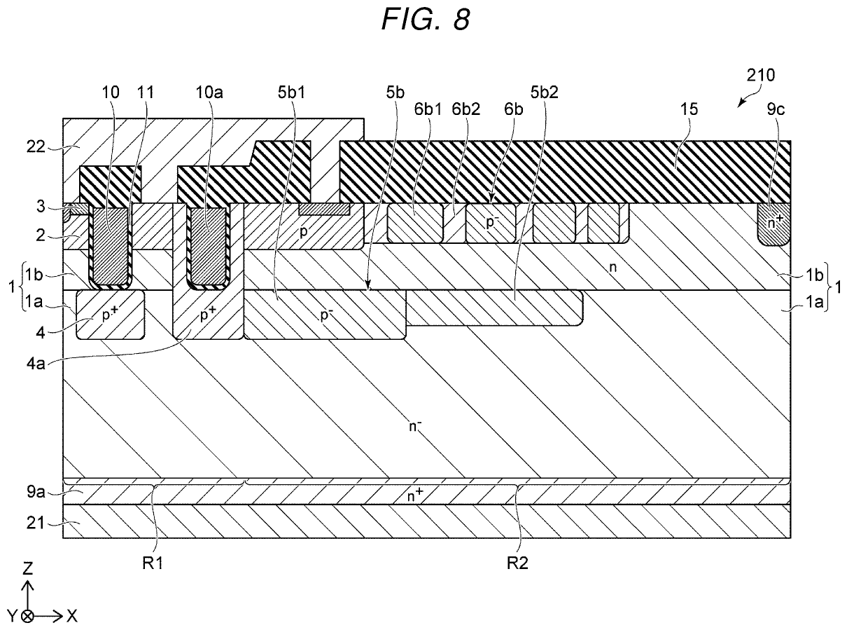

FIG. 8 is a sectional view showing a part of a semiconductor device according to a first modification of the second embodiment.

When compared with the semiconductor device 200, a semiconductor device 210 according to the first modification shown in FIG. 8 includes a p⁻-type semiconductor region 5b (which is another example of the fifth semiconductor region) in place of the plurality of p⁺-type semiconductor regions 5. The p⁻-type semiconductor region 5b is provided around the plurality of p⁺-type semiconductor regions 4 in the X-Y plane. The concentration of p-type impurities of the p⁻-type semiconductor region 5b is lower than the concentration of p-type impurities of the p⁺-type semiconductor region 4.

The p⁻-type semiconductor region 5b includes a plurality of portions 5b1 and 5b2 having different concentrations of p-type impurities. The portion 5b2 is located around the portion 5b1 in the X-Y plane. The concentration of p-type impurities of the portion 5b2 is lower than the concentration of p-type impurities of the portion 5b1. The thickness of the portion 5b2 is less than the thickness of the portion 5b1. The “thickness” as used herein corresponds to the length in the Z direction. In the example shown in FIG. 8, the p⁻-type semiconductor region 5b includes two portions 5b1 and 5b2 having different concentrations of p-type impurities and thicknesses. The p⁻-type semiconductor region 5b may include more portions having different concentrations of p-type impurities and thicknesses.

Also in a case where the p⁻-type semiconductor region 5b is provided in place of the p⁺-type semiconductor region 5, it is possible to expand the electric field distribution toward the outer periphery of the semiconductor device 210 in a location where the p⁺-type semiconductor region 4 is provided and reduce electric field concentration near the p⁺-type semiconductor region 4. This makes it possible to increase the breakdown voltage of the semiconductor device 210.

Moreover, as described earlier, by providing the p⁺-type semiconductor region 5, it is possible to reduce electric field concentration near the interface between the semiconductor region and the insulating layer 15 and further stabilize the breakdown voltage of the semiconductor device 100.

Third Embodiment

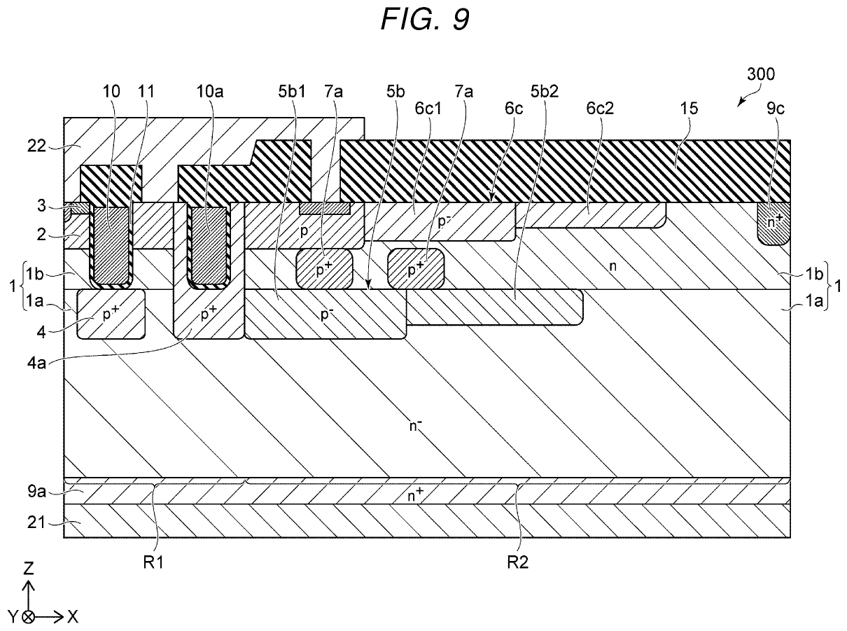

FIG. 9 is a sectional view showing a part of a semiconductor device according to a third embodiment.

In a semiconductor device 300 according to the third embodiment shown in FIG. 9, a p⁻-type semiconductor region 5b, a p⁻-type semiconductor region 6c (which is another example of the sixth semiconductor region), and a p⁺-type semiconductor region 7a (which is another example of the seventh semiconductor region) are provided in the second region R2.

As in the case of the p⁻-type semiconductor region 5b of the semiconductor device 210, the p⁻-type semiconductor region 5b of the semiconductor device 300 is provided around the plurality of p⁺-type semiconductor regions 4 in the X-Y plane. The p⁺-type semiconductor region 7a is located around the gate electrode 10 in the X-Y plane. The p⁺-type semiconductor region 7a is located above the p⁻-type semiconductor region 5b. The concentration of p-type impurities of the p⁺-type semiconductor region 7a is higher than the concentration of p-type impurities of the p-type base region 2 and higher than the concentration of p-type impurities of the p⁻-type semiconductor region 5b. A plurality of p⁺-type semiconductor regions 7a are provided in the X direction and the Y direction. The p⁻-type semiconductor regions 7a are separated from each other.

One or more of the plurality of p⁺-type semiconductor regions 7a may abut the p⁻-type semiconductor region 5b or the p-type base region 2. The plurality of p⁺-type semiconductor regions 7a may be separated from the p⁻-type semiconductor region 5b and the p-type base region 2.

The p⁻-type semiconductor region 6c is provided around the p-type base region 2 in the X-Y plane and abuts the p-type base region 2. The p⁻-type semiconductor region 6c is located above the plurality of p⁺-type semiconductor regions 7a. The p⁻-type semiconductor region 6c may abut one or more of the plurality of p⁺-type semiconductor regions 7a or may be separated from the plurality of p⁺-type semiconductor regions 7a. The concentration of p-type impurities of the p⁻-type semiconductor region 6c is lower than the concentration of p-type impurities of the p-type base region 2 and lower than the concentration of p-type impurities of the p⁺-type semiconductor region 7a.

The p⁻-type semiconductor region 6c includes a plurality of portions 6c1 and 6c2 having different concentrations of p-type impurities. The portion 6c2 is located around the portion 6c1 in the X-Y plane. The concentration of p-type impurities of the portion 6c2 is lower than the concentration of p-type impurities of the portion 6c1. The thickness of the portion 6c2 is smaller than the thickness of the portion 6c1. The p⁻-type semiconductor region 6c may include more portions having different concentrations of p-type impurities and thicknesses than those in an example shown in FIG. 9.

In the semiconductor device 300, between the p⁻-type semiconductor region 5b and the p⁻-type semiconductor region 6c, the plurality of p⁺-type semiconductor regions 7a having a higher concentration of p-type impurities than these semiconductor regions are provided. Providing the p⁺-type semiconductor regions 7a allows a depletion layer to spread more easily in the Z direction in the second region R2. This makes it possible to reduce the electric field strength in the Z direction in the second region R2 and further increase the breakdown voltage of the semiconductor device 300.

First Modification

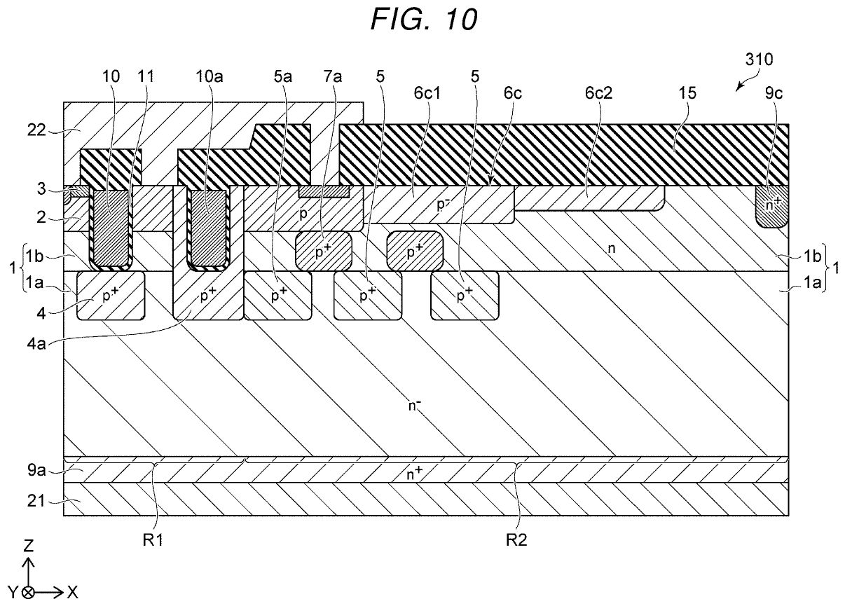

FIG. 10 is a sectional view showing a part of a semiconductor device according to a first modification of the third embodiment.

When compared with the semiconductor device 300, a semiconductor device 310 according to the first modification shown in FIG. 10 includes a plurality of p⁺-type semiconductor regions 5 in place of the p⁻-type semiconductor region 5b. The specific structure of the p⁺-type semiconductor region 5 in the semiconductor device 100, 110, or 200 is applicable to the specific structure of the p⁺-type semiconductor region 5 in the semiconductor device 310.

The concentration of p-type impurities of the p⁺-type semiconductor region 7a may be the same as the concentration of p-type impurities of the p⁺-type semiconductor region 5 or may be different therefrom. One or more of the plurality of p⁺-type semiconductor regions 7a may abut one or more of the plurality of p⁺-type semiconductor regions 5 or may be separated from the plurality of p⁺-type semiconductor regions 5.

When the plurality of p⁺-type semiconductor regions 5 are provided in place of the p⁻-type semiconductor region 5b, it is possible to reduce electric field concentration near the interface between the semiconductor region and the insulating layer 15 and further stabilize the breakdown voltage of the semiconductor device 310 as described earlier.

Second Modification

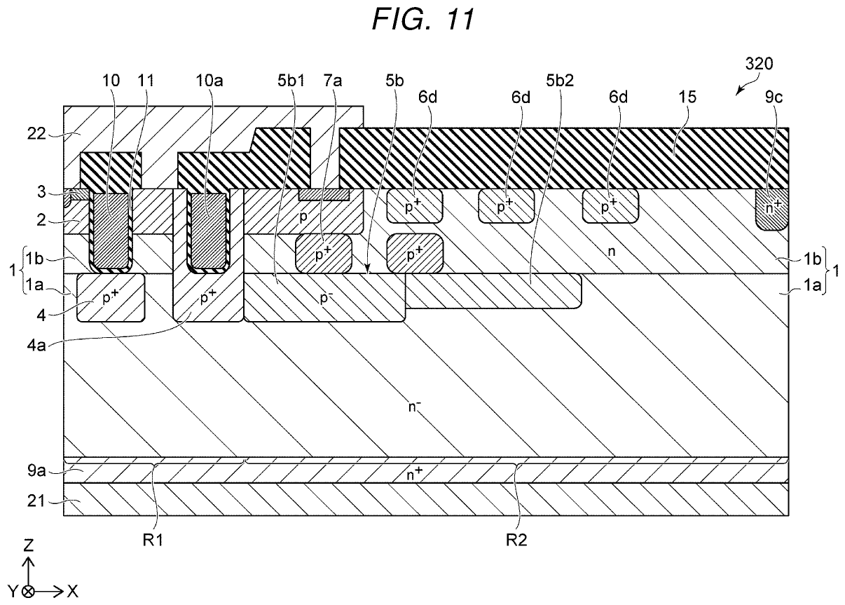

FIG. 11 is a sectional view showing a part of a semiconductor device according to a second modification of the third embodiment.

When compared with the semiconductor device 300, a semiconductor device 320 according to the second modification shown in FIG. 11 includes a p⁺-type semiconductor region 6d (which is another example of the sixth semiconductor region) in place of the p⁻-type semiconductor region 6c.

The p⁺-type semiconductor region 6d is located around the p-type base region 2 along the X-Y plane. The concentration of p-type impurities of the p⁺-type semiconductor region 6d is higher than the concentration of p-type impurities of the p-type base region 2. The concentration of p-type impurities of the p⁺-type semiconductor region 6d may be the same as the concentration of p-type impurities of the p⁺-type semiconductor region 7a or may be different therefrom. A plurality of p⁺-type semiconductor regions 6d are provided in the X direction and the Y direction. The p⁺-type semiconductor regions 6d are separated from each other and the space between the adjacent p⁺-type semiconductor regions 6d increases at positions farther from the center in the radial direction.

Of the plurality of p⁺-type semiconductor regions 6d, a p⁺-type semiconductor region 6d closest to the first region R1 may abut the p-type base region 2 or may be separated from the p-type base region 2. One or more of the plurality of p⁺-type semiconductor regions 6d may abut one or more of the plurality of p⁺-type semiconductor regions 7a or may be separated from the plurality of p⁺-type semiconductor regions 7a.

The concentration of p-type impurities of the p⁺-type semiconductor region 6d is higher than the concentration of p-type impurities of the p-type base region 2 and higher than the concentration of p-type impurities of the p⁻-type semiconductor region 5b. For example, the p⁺-type semiconductor region 6d is not completely depleted when the semiconductor device 320 is OFF. Therefore, when the semiconductor device 320 is OFF, electric field concentration occurs near the bottom of the p⁺-type semiconductor region 6d, which makes an avalanche breakdown more likely to occur. As a result, it is possible to make an avalanche breakdown more likely to occur at a spot that is distant from an interface between the portion 1b and the insulating layer 15.

Third Modification

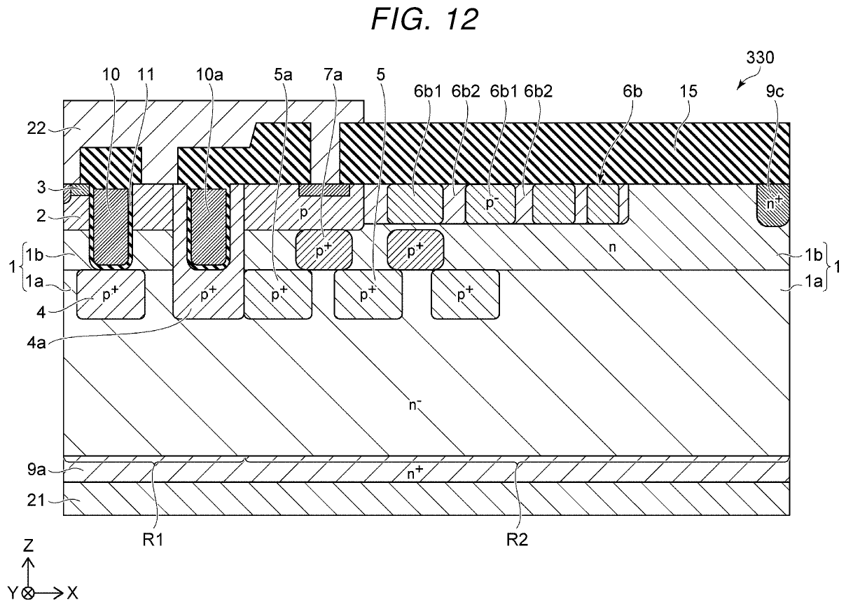

FIG. 12 is a sectional view showing a part of a semiconductor device according to a third modification of the third embodiment.

When compared with the semiconductor device 310, a semiconductor device 330 according to the third modification shown in FIG. 12 includes a p⁻-type semiconductor region 6b in place of the p⁻-type semiconductor region 6c. The specific structure of the p⁻-type semiconductor region 6b in the semiconductor device 200 is applicable to the specific structure of the p⁻-type semiconductor region 6b in the semiconductor device 330.

Fourth Modification

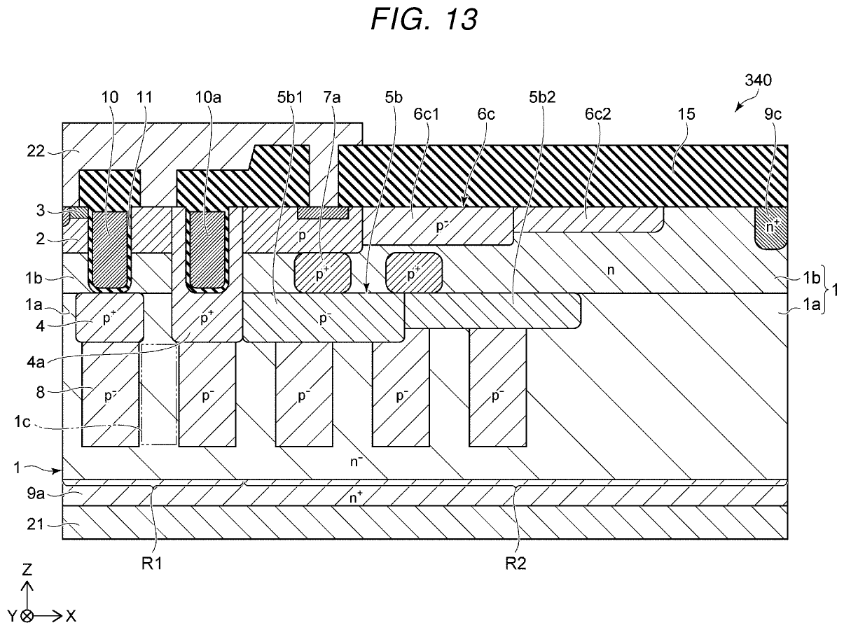

FIG. 13 is a sectional view showing a part of a semiconductor device according to a fourth modification of the third embodiment.

When compared with the semiconductor device 300, a semiconductor device 340 according to the fourth modification shown in FIG. 13 further includes a p⁻-type pillar region 8 (referred to herein as an eighth semiconductor region). The p⁻-type pillar region 8 is provided in the n⁻-type drift region 1 and located below the p⁺-type semiconductor region 4 and the p⁻-type semiconductor region 5b. The p⁻-type pillar region 8 abuts the p⁺-type semiconductor region 4 or the p⁻-type semiconductor region 5b. The n⁻-type drift region 1 further includes an n⁻-type pillar region 1c lying side-by-side with the p⁻-type pillar region 8 in the X direction. The n⁻-type pillar regions 1c and the p⁻-type pillar regions 8 are alternately provided in the X direction. Each n⁻-type pillar region 1c and each p⁻-type pillar region 8 extend in the Y direction along the gate electrode 10.

The n⁻-type pillar regions 1c and the p⁻-type pillar regions 8 which are alternately provided in the X direction allow a depletion layer to spread in the X direction from the pn junction between the n⁻-type pillar region 1c and the p⁻-type pillar region 8 when the semiconductor device 340 is OFF. This makes it possible to increase the breakdown voltage of the semiconductor device 340.

The above description deals with an example in which a plurality of p⁻-type pillar regions 8 are added to the structure of the semiconductor device 300. The embodiment is not limited to this example; a plurality of p⁻-type pillar regions 8 may be added to any one of the semiconductor devices 100, 110, 200, 210, and 310 to 330. By providing a plurality of p⁻-type pillar regions 8, it is possible to increase the breakdown voltage in any of these semiconductor devices.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure. In addition, the embodiments described herein may be carried out in combination.

What is claimed is:

1. A semiconductor device comprising:
a first electrode;
a first semiconductor region of a first conductivity type that is provided on the first electrode in a first direction and includes a first region and a second region provided around the first region;
a second semiconductor region of a second conductivity type that is provided on the first region;
a third semiconductor region of the first conductivity type that is provided on a part of the second semiconductor region;
a gate electrode that faces the second semiconductor region with a gate insulation layer placed therebetween;
a fourth semiconductor region of the second conductivity type that is provided between the first region and the gate electrode;
a plurality of fifth semiconductor regions of the second conductivity type that are provided in the second region, each located around the fourth semiconductor region in a first plane perpendicular to the first direction, and separated from each other in a second direction that extends from the first region to the second region;
a plurality of sixth semiconductor regions of the second conductivity type that are provided in the second region, located around the second semiconductor region along a second plane perpendicular to the first direction, and separated from each other in the second direction, the plurality of sixth semiconductor regions each having a concentration of impurities of the second conductivity type which is lower than a concentration of impurities of the second conductivity type of each of the plurality of fifth semiconductor regions; and
a second electrode that is provided on the second semiconductor region and the third semiconductor region.

2. The semiconductor device according to claim 1,
wherein the concentration of impurities of the second conductivity type of each of the plurality of sixth semiconductor regions is lower than a concentration of impurities of the second conductivity type of the second semiconductor region.

3. The semiconductor device according to claim 2, further comprising:
a plurality of seventh semiconductor regions of the second conductivity type that are located around the gate electrode in a third plane perpendicular to the first direction,
wherein the plurality of seventh semiconductor regions are located above the plurality of fifth semiconductor regions and located below the plurality of sixth semiconductor regions.

4. The semiconductor device according to claim 3,
wherein a concentration of impurities of the second conductivity type of each of the plurality of seventh semiconductor regions is lower than the concentration of impurities of the second conductivity type of each of the plurality of fifth semiconductor regions and higher than the concentration of impurities of the second conductivity type of each of the plurality of sixth semiconductor regions.

5. The semiconductor device according to claim 4,
wherein the plurality of seventh semiconductor regions include a first continuous semiconductor region in the third plane around the gate electrode and a second continuous semiconductor region in the third plane around the first continuous semiconductor region.

6. The semiconductor device according to claim 4,
wherein the plurality of seventh semiconductor regions include a first continuous semiconductor region in the third plane around the gate electrode and a plurality of disconnected semiconductor regions of the second conductivity type in the third plane around the first continuous semiconductor region.

7. The semiconductor device according to claim 1,
wherein a spacing between two adjacent sixth semiconductor regions in the second direction increases at positions that are farther from the first region.

8. The semiconductor device according to claim 1, further comprising:
a plurality of eighth semiconductor regions of the second conductivity type that are provided in the first semiconductor region and separated from each other in the direction perpendicular to the first direction,
wherein each of eighth semiconductor regions has a pillar-shape and has a concentration of impurities of the second conductivity type that is less than a concentration of impurities of the second conductivity type of the second semiconductor region.

9. A semiconductor device comprising:
a first electrode;
a first semiconductor region of a first conductivity type that is provided on the first electrode in a first direction and includes a first region and a second region provided around the first region;
a second semiconductor region of a second conductivity type that is provided on the first region;
a third semiconductor region of the first conductivity type that is provided of a part of the second semiconductor region;
a gate electrode that faces the second semiconductor region with a gate insulation layer placed therebetween;
a fourth semiconductor region of the second conductivity type that is provided between the first region and the gate electrode;
a fifth semiconductor region of the second conductivity type that is provided in the second region and located around the fourth semiconductor region in a first plane perpendicular to the first direction;
a sixth semiconductor region of the second conductivity type that is provided in the second region, located around the second semiconductor region in a second plane perpendicular to the first direction, and includes first portions and second portions which are alternately provided in a second direction that extends from the first region to the second region, wherein a concentration of impurities of the second conductivity type of the first portion is lower than a concentration of impurities of the second conductivity type of the second portion, and a width of each of the first portions in the second direction decreases at positions farther from the first region; and
a second electrode that is provided on the second semiconductor region and the third semiconductor region.

10. The semiconductor device according to claim 9, further comprising:
a plurality of seventh semiconductor regions of the second conductivity type that are located around the gate electrode in a third plane perpendicular to the first direction,
wherein the plurality of seventh semiconductor regions are separated from each other in the second direction, and
wherein the plurality of seventh semiconductor regions are located above the fifth semiconductor region and located below the sixth semiconductor region.

11. The semiconductor device according to claim 10,
wherein a concentration of impurities of the second conductivity type of each of the plurality of seventh semiconductor regions is higher than the concentration of impurities of the second conductivity type of the first portion and higher than the concentration of impurities of the second conductivity type of the second portion.

12. The semiconductor device according to claim 9,
wherein the fifth semiconductor region includes a first part that is provided around the fourth semiconductor region in the first plane and a second part that is provided around the first portion in the first plane.

13. The semiconductor device according to claim 12,
wherein a concentration of impurities of the second conductivity type of the first part is higher than the concentration of impurities of the second conductivity type of the second part.

14. The semiconductor device according to claim 13,
wherein a thickness of the first part is greater than a thickness of the second part.

15. The semiconductor device according to claim 9, further comprising:
a plurality of eighth semiconductor regions of the second conductivity type that are provided in the first semiconductor region and separated from each other in the direction perpendicular to the first direction,
wherein each of eighth semiconductor regions has a pillar-shape and has a concentration of impurities of the second conductivity type that is less than a concentration of impurities of the second conductivity type of the second semiconductor region.

16. A semiconductor device comprising:
a first electrode;
a first semiconductor region of a first conductivity type that is provided on the first electrode in a first direction and includes a first region and a second region provided around the first region;
a second semiconductor region of a second conductivity type that is provided on the first region;
a third semiconductor region of the first conductivity type that is provided on a part of the second semiconductor region;
a gate electrode that faces the second semiconductor region with a gate insulation layer placed therebetween;
a fourth semiconductor region of the second conductivity type that is provided between the first region and the gate electrode;
a fifth semiconductor region of the second conductivity type that is provided in the second region and located around the fourth semiconductor region in a first plane perpendicular to the first direction;
a sixth semiconductor region of the second conductivity type that is provided in the second region and located around the second semiconductor region in a second plane perpendicular to the first direction;
a plurality of seventh semiconductor regions of the second conductivity type that are located around the gate electrode in a third plane perpendicular to the first direction, separated from each other in a second direction that extends from the first region to the second region, located above the fifth semiconductor region, and located below the sixth semiconductor region; and
a second electrode that is provided on the second semiconductor region and the third semiconductor region.

17. The semiconductor device according to claim 16,
wherein the fifth semiconductor region includes a first part that is provided around the second semiconductor region in the first plane, a second part that is provided around the first part in the first plane, and
wherein the sixth semiconductor region includes a first portion that is provided around the second semiconductor region in the second plane, a second portion that is provided around the first portion in the second plane, and a third portion that is provided around the second portion in the second plane.

18. The semiconductor device according to claim 17,
wherein a spacing between the first portion and the second portion is less than a spacing between the second portion and the third portion.

19. The semiconductor device according to claim 17,
wherein a width of the first portion is greater than a width of the second portion, which is greater than a width of the third portion.

20. The semiconductor device according to claim 17,
wherein a thickness of the first portion is greater than a thickness of the second portion, which is greater than a thickness of the third portion, and
wherein a thickness of the first part is greater than a thickness of the second part.
